(19) United States
(12) Patent Application Publication
(10) Pub. No.: US 2018/0165032 A1
(43) Pub. Date: Jun. 14, 2018

(54) READ WRITE PERFORMANCE FOR NAND FLASH FOR ARCHIVAL APPLICATION

(71) Applicant: Western Digital Technologies, Inc., Irvine, CA (US)

(72) Inventors: Zvonimir Z. BANDIC, San Jose, CA (US); Minghai QIN, San Jose, CA (US); Chao SUN, San Jose, CA (US)

(73) Assignee: Western Digital Technologies, Inc.

(21) Appl. No.: 15/379,203

(22) Filed: Dec. 14, 2016

(51) Int. Cl. G06F 3/06; G11C 11/56

(52) U.S. Cl. CPC G06F 3/0634; G11C 11/56; G06F 3/0679; G06F 3/061

(57) ABSTRACT

The present disclosure generally relates to a method for reading and writing data for archival applications in a multiple-level cell memory device. In one embodiment, a method includes operating the multiple-level cell memory device in a single-level cell mode until all blocks are written, changing the single-level cell mode to a first multiple-level cell mode to generate additional space in each block, and operating the multiple-level cell device in the first multiple-level cell mode until all additional space in each block is written. Since the read and write speeds are faster in the single-level cell mode, read and write performances of the multiple-level cell memory device are improved.

### BACKGROUND OF THE DISCLOSURE

### Field of the Disclosure

Embodiments of the present disclosure generally relate a method for reading and writing data for archival applications in a multiple-level cell memory device.

### Description of the Related Art

Non-volatile devices, such as flash memory based solid-state drive (SSD) devices having NAND flash memory, have become the preferred technology for many applications in recent years. The ability to store large amounts of data and to withstand harsh operating environment, together with the non-volatile nature of the storage, makes these flash storage devices appealing for many applications.

Multiple-level cell technology has been utilized in NAND flash to lower cost per unit of storage by increase data density. Unlike a single-level cell (SLC) flash NAND memory, which can store one bit per cell, multiple-level cell flash NAND memory can store multiple bits per cell. For example, a multi-level cell (MLC) flash NAND memory can store two bits per cell, a triple-level cell (TLC) flash NAND memory can store three bits per cell, and a quad-level cell (QLC) flash NAND memory can store four bits per cell. As NAND supports more and more levels, the read and write speeds will be sacrificed, especially for read latency, since more read thresholds need to be applied to retrieve the stored data. For archival applications, which are write-few-read-many applications, read performance is important.

Therefore, an improved method for reading and writing data for archival applications in a multi-level cell memory device is needed.

### SUMMARY OF THE DISCLOSURE

The present disclosure generally relates to a method for reading and writing data for archival applications in a multiple-level cell memory device. In one embodiment, a method includes operating the multiple-level cell memory device in a single-level cell mode until all blocks are written, changing the single-level cell mode to a first multiple-level cell mode to generate additional space in each block, and operating the multiple-level cell device in the first multiple-level cell mode until all additional space in each block is written. Since the read and write speeds are faster in the single-level cell mode, read and write performances of the multiple-level cell memory device are improved.

In one embodiment, a method comprises operating a multiple-level cell memory device in a single-level cell mode until all blocks are written, changing the single level cell mode to a first multiple-level cell mode to generate first additional space in each block, and operating the multiple-level cell device in the first multiple-level cell mode until all first additional space in each block is written.

In another embodiment, a data storage device comprises a controller, a memory, and a storage medium storing instructions that, when executed by the controller, cause the data storage device to operate the data storage device in a single-level cell mode until all blocks are written, change the single-level cell mode to a first multiple-level cell mode to generate first additional space in each block, and operate the data storage device in the first multiple-level cell mode until all first additional space in each block is written.

In another embodiment, a non-transitory computer readable storage medium, containing instructions that, when executed by a controller, cause a data storage device to perform read and write processes, by performing the steps of: operating a multiple-level cell memory device in a single-level cell mode until all blocks are written, changing the single level cell mode to a first multiple-level cell mode to generate first additional space in each block, and operating the multiple-level cell device in the first multiple-level cell mode until all first additional space in each block is written.

In another embodiment, a data storage device comprises means for operating a multiple-level cell memory device in a single-level cell mode until all blocks are written, means for changing the single-level cell mode to a first multiple-level cell mode to generate first additional space in each block, and means for operating the multiple-level cell device in the first multiple-level cell mode until all first additional space in each block is written.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a block diagram of an example electronic system including a data storage device according to one embodiment described herein.

FIG. 2 is a flow diagram of a method for reading from and writing to the data storage device according to one embodiment described herein.

FIG. 3 is a flow diagram of a method for reading from and writing to the data storage device according to another embodiment described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

The present disclosure generally relates to a method for reading and writing data for archival applications in a multiple-level cell memory device. In one embodiment, a method includes operating the multiple-level cell memory device in a single-level cell mode until all blocks are written, changing the single-level cell mode to a first multiple-level cell mode to generate additional space in each block, and operating the multiple-level cell device in the first multiple-level cell mode until all additional space in each block is written. Since the read and write speeds are faster in the single-level cell mode, read and write performances of the multiple-level cell memory device are improved.

FIG. 1 illustrates an electronic system 100 according to one embodiment described herein. The electronic system 100 includes a data storage device 110 and a host 104 coupled to the data storage device 110. The host 104 may be any device configured to be coupled to the data storage device 110 and to store data in the data storage device 110. The host 104 may be any computing or electronic device, such as a computer workstation, an embedded computing system, a network router, a laptop computer, a personal digital assistant, a digital camera, a cellular phone, or a tablet. The data storage device 110 may be any suitable non-volatile memory device for storing data, such as a flash memory based SSD, a flash memory card, or a flash storage array.

The data storage device 110 includes a host interface 105, a data storage controller 101, a storage medium 102, and a flash memory 103. The controller 101 may use storage medium 102 for temporary storage of data and information used to manage data storage device 110. The controller 101 may include several internal components (not shown) such as a read-only memory, a flash component interface (for example, a multiplexer to manage instruction and data transport along a serial connection to the flash memory 103), an I/O interface, error correction circuitry, and the like. In some embodiments, all of the components of the controller 101 may be integrated into a single chip. In other embodiments, the components of the controller 101 may be separated on their own PC board. The controller 101 may also include a processor configured to execute code or instructions to perform the operations and functionality described herein, to manage request flow and address mappings, and to perform calculations and generate commands. The processor of the controller 101 is configured to monitor and control the operation of the components in the data storage device 110, such as to change the operation mode of the data storage device 110. The processor may be a general-purpose microprocessor, a microcontroller, a digital signal processor (DSP), an application specific integrated circuit (ASIC), a field programmable gate array (FPGA), a programmable logic device (PLD), a state machine, gated logic, discrete hardware components, or a combination thereof. One or more sequences of instructions may be stored as firmware on ROM within the controller 101 and/or its processor. One or more sequences of instructions may be software stored and read from the storage medium 102, the flash memory 103, or received from the host 104 (for example, via the host interface 105). ROM and the storage medium 102 may represent examples of machine or computer readable media on which instructions/code executable by controller 101 and/or its processor may be stored. Machine or computer readable media may generally refer to any medium or media used to provide instructions to the controller 101 and/or its processor, including both volatile media, such as dynamic memory used for the storage medium 102 or for buffers within the controller 101, and non-volatile media, such as electronic media, optical media, and magnetic media.

In some embodiments, the controller 101 is configured to store data received from the host 104 in the flash memory 103 in response to a write command from the host 104. The controller 101 is further configured to read data stored in the flash memory 103 and to transfer the read data to the host 104 in response to a read command from the host 104. As will be described in more detail below, the controller 101 is configured to, on determining certain operating conditions are present, change the operation mode of the data storage device 110.

The storage medium 102 may be volatile memory used to temporarily store data and information used to manage the data storage device 110. In one embodiment, the storage medium 102 is random access memory (RAM) such as double data rate (DDR) RAM. Other types of RAM also may be used to implement the storage medium 102. While the storage medium 102 is depicted as being distinct from the controller 101, those skilled in the art will recognize that the storage medium 102 may be incorporated into the controller 101 without departing from the scope of the subject technology. Alternatively, the storage medium 102 may be a non-volatile memory such as a magnetic disk, flash memory, peripheral SSD, and the like.

The host interface 105 is configured to be coupled to the host 104, to receive data from the host 104 and to send data to the host 104. Host interface 105 may include both electrical and physical connections for operably coupling the host 104 to the controller 101, for example, via the I/O interface of the controller 101. The host interface 105 is configured to communicate data, addresses, and control signals between the host 104 and the controller 101. Alternatively, the I/O interface of controller 101 may include and/or be combined with the host interface 105. The host interface 105 may be configured to implement a standard interface, such as Serial-Attached SCSI (SAS), Fiber Channel interface, PCI Express (PCIe), SATA, USB, and the like. The host interface 105 may be configured to implement only one interface. Alternatively, the host interface 105 (and/or the I/O interface of controller 101) may be configured to implement multiple interfaces, which are individually selectable using a configuration parameter selected by a user or programmed at the time of assembly. The host interface 105 may include one or more buffers for buffering transmissions between the host 104 and the controller 101.

The flash memory 103 may be any multiple-level cell memory. The multiple-level cell memory device is referring to a memory device including memory cells each having more than two voltage levels. For example, the flash memory 103 may be a MLC flash NAND memory including cells each having four levels, a TLC flash NAND memory including cells each having eight levels, or a QLC flash NAND memory including cells each having 16 levels. The level used herein is referring to a voltage level. The flash memory 103 may include a single flash memory chip, or, as shown in FIG. 1, may include multiple flash memory chips arranged in multiple channels.

The flash memory 103 may have a standard interface specification. This standard ensures that chips from multiple manufacturers can be used interchangeably (at least to a large degree). The interface may further hide the inner working of the flash memory 103 and return only internally detected bit values for data. The interface of flash memory 103 may be used to access one or more internal registers 106 and an internal flash controller 107. In some aspects, the registers 106 may include address, command, control, and/or data registers, which internally retrieve and output the necessary data to and from a NAND memory cell array 108. For example, a data register may include data to be stored in the memory array 108, or data after a fetch from the memory array 108, and may also be used for temporary data storage and/or act like a buffer. An address register may store the memory address from which data will be fetched to the host 104 or the address to which data will be sent and stored. In some embodiments, a command register may be included to control parity, interrupt control, and/or the like. In some embodiments, the internal flash controller 107 is accessible via a control register to control the general behavior of the flash memory 103. The internal flash controller 107 and/or the control register may control the number of stop bits, word length, receiver clock source, and may also control switching the addressing mode, paging control, coprocessor control, and the like.

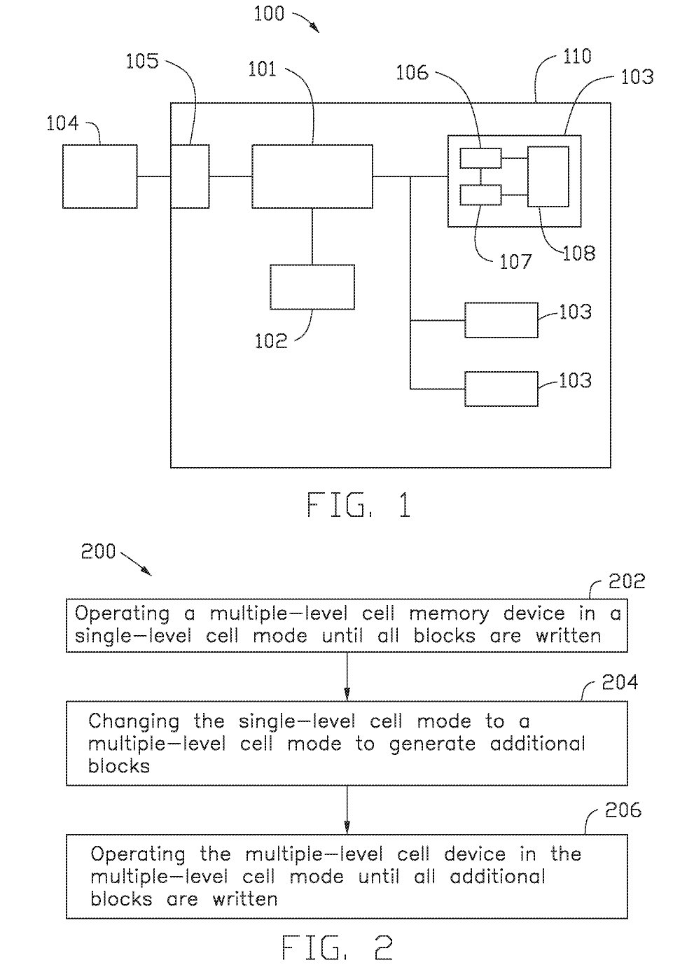

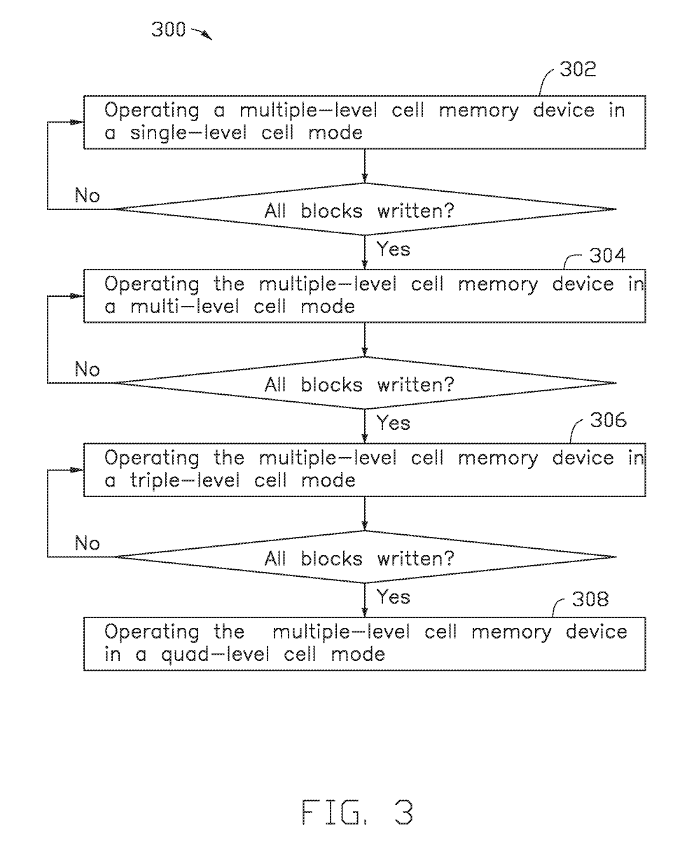

FIG. 2 is a flow diagram of a method 200 for reading from and writing to a data storage device, such as the data storage device 110 shown in FIG. 1 according to one embodiment described herein. The method 200 starts at block 202, which is operating a multiple-level cell memory device in a SLC mode until all blocks are written. The multiple-level cell memory device may be any suitable data storage device including memory cells each having more than two voltage levels. The level used herein is referring to a voltage level. For example, the multiple-level cell memory device may include a MLC flash NAND memory including cells each having four levels, a TLC flash NAND memory including cells each having eight levels, or a QLC flash NAND memory including cells each having 16 levels. The multiple-level cell memory device may be the data storage device 110 shown in FIG. 1. The amount of data that can be stored (written) in the multiple-level cell memory device in the SLC mode may be less than when multiple-level cell mode, such as MLC, TLC or QLC, is used. For example, a 10 terabytes QLC flash NAND memory device can store 10 terabytes of data when operated in the QLC mode, since there are 16 levels of blocks can be written. If the 10 terabytes QLC flash NAND memory device is operating in the SLC mode, only about 2.5 terabytes of data can be stored in the 10 terabytes QLC flash NAND memory device, since only 2 levels of blocks can be written. Operating the multiple-level cell memory device at a level below the maximum number of levels increases the read and write speeds. For example, the read and write speeds are faster in the SLC mode than in the MLC, TLC or QLC mode, the read and write speeds are faster in the MLC mode than in the TLC or QLC mode for the QLC flash NAND memory device, and the read and write speeds are faster in the TLC mode than in QLC mode for a QLC flash NAND memory device.

After all of the available blocks in the SLC mode are written, the SLC mode is changed to a multiple-level mode to generate additional space in each block for writing, as shown at block 204. The modes of operation of the multiple-level cell device can be changed by a controller, such as the controller 101 shown in FIG. 1. As the operation mode is changed from the SLC mode to a multiple-level cell mode, such as MLC mode, TLC mode, or QLC mode, additional space in each block is generated since the number of voltage levels in each cell has increased. Next, at block 206, the multiple-level cell device operates in the multiple-level cell mode until all additional space in each block is written.

The method 200 may be utilized for archival applications, in which data is written once but read many times. Examples of archival applications include posting photos or videos on a website or placing documents in archival systems. For archival applications, especially in consumer devices, the multiple-level cell device may have large empty spaces for a while. By operating the multiple-level cell device in the SLC mode initially, read and write speeds are increased, leading to improved read and write performances.

FIG. 3 is a flow diagram of a method 300 for reading from and writing to a data storage device, such as the data storage device 110 shown in FIG. 1 according to another embodiment described herein. The method 300 starts at block 302, which is operating a multiple-level cell memory device in a SLC mode. In one embodiment, the multiple-level cell memory device is a 10 terabytes QLC flash NAND memory device. The read and write speeds are faster in the SLC mode than in the QLC mode. The read speed is about 3.75 times faster when operating in the SLC mode compared to operating in the QLC mode. After all available blocks in the SLC mode are written, the multiple-level cell memory device is operating in a MLC mode, as shown at block 304. By changing the operating mode from the SLC mode to the MLC mode, additional space in each block is generated for writing in the multiple-level cell memory device. The read and write speeds are faster in the MLC mode than in the QLC mode. The read speed is about 2.5 times faster when operating in the MLC mode compared to operating in the QLC mode. After all available space in blocks in the MLC mode are written, the multiple-level cell memory device is operating in a TLC mode, as shown at block 306. By changing the operating mode from the MLC mode to the TLC mode, additional space in each block is generated for writing in the multiple-level cell memory device. The read and write speeds are faster in the TLC mode than in the QLC mode. The read speed is about 1.61 times faster when operating in the TLC mode compared to operating in the QLC mode. After all available space in blocks in the TLC mode are written, the multiple-level cell memory device is operating in a QLC mode, as shown at block 308. By changing the operating mode from the TLC mode to the QLC mode, additional space in each block is generated for writing in the multiple-level cell memory device.

The benefits of the method 300 can be illustrated by the following example. Assuming a person stores 5 gigabytes of data in a 10 terabytes QLC flash memory device every day. For the first 500 days, the 10 terabytes QLC flash memory device is operating in the SLC mode, which has a 3.75 times faster read speed than the QLC mode. At the end of the first 500 days, 2.5 terabytes of data are stored in the 10 terabytes QLC flash memory device, and there are no more available blocks for writing. The SLC mode is then changed to the MLC mode, which generates additional space in each block for writing. For the next 500 days, the 10 terabytes QLC flash memory device is operating in the MLC mode, which has a 2.5 times faster read speed than the QLC mode. At the end of the 1000 days, 5.0 terabytes of data are stored in the 10 terabytes QLC flash memory device, and there is no more available space in blocks for writing. The MLC mode is then changed to the TLC mode, which generates additional space in each block for writing. For the next 500 days, the 10 terabytes QLC flash memory device is operating in the TLC mode, which has a 1.61 times faster read speed than the QLC mode. At the end of the 1500 days, 7.5 terabytes of data are stored in the 10 terabytes QLC flash memory device, and there is no more available space in blocks for writing. The TLC mode is then changed to the QLC mode, which generates additional space in each block for writing. Without changing the mode of operation, the 10 terabytes QLC flash memory device operates in the QLC mode, which has slower read and write speeds compared to the SLC, MLC and TLC modes. By changing the mode of operation, the memory device can be used more efficiently due to the increased read and write speeds.

While the foregoing is directed to embodiments of the present disclosure, other and further embodiments of the disclosure may be devised without departing from the basic scope thereof, and the scope thereof is determined by the claims that follow.

What is claimed is:

1. A method, comprising:
operating a multiple-level cell memory device in a single-level cell mode until all blocks are written;
changing the single-level cell mode to a first multiple-level cell mode to generate first additional space in each block; and
operating the multiple-level cell device in the first multiple-level cell mode until all first additional space in each block is written.

2. The method of claim 1, further comprising changing the first multiple-level cell mode to a second multiple-level cell mode to generate second additional space in each block.

3. The method of claim 2, further comprising operating the multiple-level cell device in the second multiple-level cell mode until all second additional space in each block is written.

4. The method of claim 3, further comprising changing the second multiple-level cell mode to third multiple-level cell mode to generate third additional space in each block.

5. The method of claim 4, further comprising operating the multiple-level cell device in the third multiple-level cell mode until all third additional space in each block is written.

6. The method of claim 5, wherein the multiple-level cell memory device is a quad-level cell memory device.

7. The method of claim 6, wherein the first multiple-level cell mode is a multi-level cell mode, the second multiple-level cell mode is a triple-level cell mode, and the third multiple-level cell mode is a quad-level cell mode.

8. A data storage device, comprising:
a controller;
a memory; and
a storage medium storing instructions that, when executed by the controller, cause the data storage device to:
operate the data storage device in a single-level cell mode until all blocks are written;
change the single-level cell mode to a first multiple-level cell mode to generate first additional space in each block; and
operate the data storage device in the first multiple-level cell mode until all first additional space in each block is written.

9. The data storage device of claim 8, further comprising change the first multiple-level cell mode to a second multiple-level cell mode to generate second additional space in each block.

10. The data storage device of claim 9, further comprising operate the multiple-level cell device in the second multiple-level cell mode until all second additional space in each block is written.

11. The data storage device of claim 10, further comprising change the second multiple-level cell mode to third multiple-level cell mode to generate third additional space in each block.

12. The data storage device of claim 11, further comprising operate the multiple-level cell device in the third multiple-level cell mode until all third additional space in each block is written.

13. The data storage device of claim 12, wherein the multiple-level cell memory device is a quad-level cell memory device.

14. The data storage device of claim 13, wherein the first multiple-level cell mode is a multi-level cell mode, the second multiple-level cell mode is a triple-level cell mode, and the third multiple-level cell mode is a quad-level cell mode.

15. A non-transitory computer readable storage medium, containing instructions that, when executed by a controller, cause a data storage device to perform read and write processes, by performing the steps of:
operating the data storage device in a single-level cell mode until all blocks are written;
changing the single-level cell mode to a first multiple-level cell mode to generate first additional space in each block; and
operating the data storage device in the first multiple-level cell mode until all first additional space in each block is written.

16. The storage medium of claim 15, further comprising changing the first multiple-level cell mode to a second multiple-level cell mode to generate second additional space in each block.

17. The storage medium of claim 16, further comprising operating the multiple-level cell device in the second multiple-level cell mode until all second additional space in each block is written.

18. The storage medium of claim 17, further comprising changing the second multiple-level cell mode to third multiple-level cell mode to generate third additional space in each block.

19. The storage medium of claim 18, wherein the multiple-level cell memory device is a quad-level cell memory device.

20. The storage medium of claim 19, wherein the first multiple-level cell mode is a multi-level cell mode, the second multiple-level cell mode is a triple-level cell mode, and the third multiple-level cell mode is a quad-level cell mode.

21. A data storage device, comprising:
means for operating a multiple-level cell memory device in a single-level cell mode until all blocks are written;
means for changing the single-level cell mode to a first multiple-level cell mode to generate first additional space in each block; and
means for operating the multiple-level cell device in the first multiple-level cell mode until all first additional space in each block is written.

22. The data storage device of claim 21, further comprising means for changing the first multiple-level cell mode to a second multiple-level cell mode to generate second additional space in each block.

23. The data storage device of claim 22, further comprising means for operating the multiple-level cell device in the second multiple-level cell mode until all second additional space in each block is written.

24. The data storage device of claim 23, further comprising means for changing the second multiple-level cell mode to third multiple-level cell mode to generate third additional space in each block.

25. The data storage device of claim 24, further comprising means for operating the multiple-level cell device in the third multiple-level cell mode until all third additional space in each block is written.

26. The data storage device of claim 25, wherein the multiple-level cell memory device is a quad-level cell memory device.

27. The data storage device of claim 26, wherein the first multiple-level cell mode is a multi-level cell mode, the second multiple-level cell mode is a triple-level cell mode, and the third multiple-level cell mode is a quad-level cell mode.
